(19) United States
(12) Patent Application Publication
(10) Pub. No.: US 2014/0034976 A1
(43) Pub. Date: Feb. 6, 2014

(54) LIGHT-EMITTING DIODE STRUCTURE AND METHOD FOR MANUFACTURING THE SAME

(71) Applicant: CHI MEI LIGHTING TECHNOLOGY CORP., Tainan (TW)

(72) Inventors: Chang-Hsin Chu, Tainan (TW); Hsueh Lin Lee, Tainan (TW); Chih Kuei Hsu, Tainan (TW); Yuan Tze Chen, Tainan (TW); Hao-Ching Wu, Tainan (TW)

(73) Assignee: CHI MEI LIGHTING TECHNOLOGY CORP., Tainan (TW)

(21) Appl. No.: 13/711,268

(22) Filed: Dec. 11, 2012

(30) Foreign Application Priority Data
Aug. 3, 2012 (TW) 101128042

(51) Int. Cl. H01L 33/08

(52) U.S. Cl. CPC H01L 33/08
USPC 257/93; 438/34

(57) ABSTRACT

A light-emitting diode (LED) structure and a method for manufacturing the same. The LED structure includes an insulation substrate, a plurality of LED chips and a plurality of interconnection layers. Each LED chip includes an epitaxial layer and a dielectric layer stacked on a surface of the insulation substrate in sequence. Each LED chip is formed with a first conductivity type contact hole and a second conductivity type contact hole penetrating the dielectric layer, and a first isolation trench disposed in the epitaxial layer and between the second conductivity type contact hole of the LED chip and the first conductivity type contact hole of the neighboring LED chip. Each interconnection layer extends from the second conductivity type contact hole of each LED chip to the first conductivity type contact hole of the neighboring LED chip by passing over the first isolation trench to electrically connect the LED chips.

### CROSS-REFERENCE TO RELATED APPLICATION

This non-provisional application claims priority under 35 U.S.C. §119(a) on Patent Application No. 101128042 filed in Taiwan R.O.C on Aug. 3, 2012, the entire contents of which are hereby incorporated by reference.

Some references, if any, which may include patents, patent applications and various publications, may be cited and discussed in the description of this invention. The citation and/or discussion of such references, if any, is provided merely to clarify the description of the present invention and is not an admission that any such reference is “prior art” to the invention described herein. All references listed, cited and/or discussed in this specification are incorporated herein by reference in their entireties and to the same extent as if each reference was individually incorporated by reference.

### FIELD OF THE INVENTION

The present invention relates to a light-emitting structure, and more particularly to a light-emitting diode (LED) structure and a method for manufacturing the same.

### BACKGROUND OF THE INVENTION

FIG. 1 is a partial sectional view of a conventional series LED structure. The conventional series LED structure 100 includes a plurality of series connected LED chips, for example, LED chips 106a and 106b, disposed on a surface 104 of an insulating substrate 102. The two neighboring LED chips 106a and 106b are separated from each other by an isolation trench 122. Each of the LED chips 106a and 106b includes an undoped semiconductor layer 108, a first conductivity type semiconductor layer 110, an active layer 112, a second conductivity type semiconductor layer 114 and a transparent conductive layer 116 stacked in sequence on a surface of the insulating substrate 102.

Each of the LED chips 106a and 106b has a mesa structure 128 and an exposed part 130 of the first conductivity type semiconductor layer 110. A first conductivity type electrode pad 118a and a second conductivity type electrode pad 120a of the LED chip 106a are respectively disposed on the exposed part 130 of the first conductivity type semiconductor layer 110 and the mesa structure 128. Likewise, a first conductivity type electrode pad 118b and a second conductivity type electrode pad 120b of the LED chip 106b are respectively disposed on the exposed part 130 of the first conductivity type semiconductor layer 110 and the mesa structure 128.

In the LED structure 100, an insulating layer 124 covers the isolation trench 122, and extends on the first conductivity type semiconductor layer 110 of the LED chip 106a and the transparent conductive layer 116 of the LED chip 106b outside an opening of the isolation trench 122, so as to electrically isolate the two neighboring LED chips 106a and 106b. To connect the two neighboring LED chips 106a and 106b in series, the LED structure 100 has an interconnection layer 126. The interconnection layer 126 extends from the first conductivity type electrode pad 118a of the LED chip 106a, through the exposed part 130 of the first conductivity type semiconductor layer 110 and the insulating layer 124 inside the isolation trench 122, onto the insulating layer 124 and the second conductivity type electrode pad 120b of the neighboring LED chip 106b, so as to electrically connect the neighboring LED chips 106a and 106b in series.

Generally speaking, such a series LED structure 100 is driven by a high voltage, so a driving circuit has high efficiency. Secondly, compared with a plurality of independent LED chips, bonding pads of the series LED structure 100 occupy a small area, so the LED structure 100 has a large light-emitting area. In addition, the current of the series LED structure 100 can be spread over every small LED chip, so the current distribution is more uniform than that of a single large-area LED chip, and therefore, the series LED structure 100 achieves better luminous efficiency.

However, a bottom of the isolation trench 122 of such a conventional series LED structure 100 needs to extend downwards to the surface 104 of the insulating substrate 102, so the isolation trench 122 has an excessive aspect ratio, so that the material of the insulating layer 124 is not easily filled, which easily causes discontinuous deposition, resulting in that pores are easily generated in the insulating layer 124. Therefore, during subsequent deposition of the conductive interconnection layer 126, the conductive material of the interconnection layer 126 may be filled in the pores of the insulating layer 124, resulting in short circuit.

In the series LED structure 100, once the LED chip 106a or 106b is short-circuited, the whole series LED structure 100 cannot operate. Therefore, the production yield of the series LED structure 100 is low.

Moreover, the excessive aspect ratio of the isolation trench 122 also easily causes discontinuous deposition of the interconnection layer 126, which will result in disconnection of the interconnection layer 126. In the series LED structure 100, once the LED chip 106a or 106b is disconnected, the whole series LED structure 100 also cannot operate. Therefore, the production yield of the series LED structure 100 is low.

In addition, when it is intended to detect whether a single LED chip is short-circuited, a reverse voltage is applied to the LED chip, and then detection is performed through measuring whether a reverse leakage current is produced. However, the series LED structure 100 is formed by a plurality of LED chips 106a, 106b and the like connected in series, so once the LED chip 106a or 106b is short-circuited, or the interconnection layer 126 of the LED chip 106a or 106b is disconnected, no reverse leakage current can be measured in the whole series LED structure 100. Therefore, it cannot be determined through measurement whether the series LED structure 100 has a short circuit defect.

Therefore, a heretofore unaddressed need exists in the art to address the aforementioned deficiencies and inadequacies.

### SUMMARY OF THE INVENTION

In one aspect, the present invention is directed to an LED structure and a method for manufacturing the same, where an interconnection layer directly extends from a contact hole in a dielectric layer above one of neighboring LED chips, through the dielectric layer, onto a contact hole in a dielectric layer above the other one of the neighboring LED chips. Therefore, conductive material may not have to be filled in an isolation trench between the two neighboring LED chips, thereby solving the disconnection problem of an interconnection layer.

In another aspect, the present invention is directed to an LED structure and a method for manufacturing the same, where an isolation trench between two neighboring LED chips is only filled with an insulating layer instead of conductive material. Therefore, even if the insulating layer in the isolation trench is deposited discontinuously, in the condition that no conductive material exists in the isolation trench, no short circuit problem is generated in a light-emitting area.

In still another aspect, the present invention is directed to an LED structure and a method for manufacturing the same, which may effectively solve the short circuit and disconnection problems, so that the production yield of the series LED structure may be improved greatly, thereby reducing the manufacturing cost.

In a further aspect, the present invention is directed to an LED structure and a method for manufacturing the same, which may effectively solve the short circuit and disconnection problems, so that the reverse leakage current detection means is not required.

In yet another aspect of the present invention, an LED structure is provided. The LED structure includes an insulating substrate, a plurality of LED chips and a plurality of interconnection layers. Each of the LED chips includes an epitaxial layer and a dielectric layer stacked in sequence on a surface of the insulating substrate. Each of the LED chips is provided with a first conductivity type contact hole and a second conductivity type contact hole that penetrate the dielectric layer, and a first isolation trench located in the epitaxial layer and between the second conductivity type contact hole of the LED chip and the first conductivity type contact hole of a neighboring LED chip. Each interconnection layer extends from the second conductivity type contact hole in each LED chip, through the above of the first isolation trench, onto the first conductivity type contact hole of a neighboring LED chip, so as to electrically connect the LED chips.

According to an embodiment of the present invention, each of the epitaxial layers includes an undoped semiconductor layer, a first conductivity type semiconductor layer, an active layer and a second conductivity type semiconductor layer stacked in sequence on a surface of the insulating substrate, and a conductivity type of the first conductivity type semiconductor layer is different from that of the second conductivity type semiconductor layer.

According to another embodiment of the present invention, each of the LED chips further includes a transparent conductive layer located between the dielectric layer and the epitaxial layer. A bottom of the first conductivity type contact hole exposes the first conductivity type semiconductor layer, and a bottom of the second conductivity type contact hole exposes the transparent conductive layer.

According to still another embodiment of the present invention, each of the LED chips further includes at least one current blocking layer located between the bottom of the second conductivity type contact hole and the epitaxial layer.

According to yet another embodiment of the present invention, in each of the LED chips, the epitaxial layer has a groove, a bottom of the groove exposes the first conductivity type semiconductor layer, the first conductivity type contact hole exposes a part of the bottom of the groove, and the dielectric layer covers a sidewall of the groove.

According to yet another embodiment of the present invention, each of the LED chips further includes an insulating layer, and the insulating layer is filled in the first isolation trench, so as to close an opening of the first isolation trench.

According to yet another embodiment of the present invention, each of the LED chips further includes at least one insulating liner covering a sidewall of the first conductivity type contact hole.

In a further aspect, a method for manufacturing an LED structure is further provided, which includes the following steps. An insulating substrate is provided. An epitaxial structure is formed on a surface of the insulating substrate. A plurality of first isolation trenches and a plurality of second isolation trenches are formed in the epitaxial structure, so as to define a plurality of epitaxial layers of a plurality of LED chips. The first isolation trenches are respectively adjacent to the second isolation trenches. A plurality of dielectric layers are formed to respectively cover the epitaxial layers. In each of the LED chips, a first conductivity type contact hole and a second conductivity type contact hole that penetrate the dielectric layer are formed. In each of the LED chips, the first isolation trench is located between the second conductivity type contact hole of the LED chip and the first conductivity type contact hole of a neighboring LED chip. A plurality of interconnection layers are formed. Each of the interconnection layers extends from the second conductivity type contact hole of each LED chip, through the above of the first isolation trench, onto the first conductivity type contact hole of the neighboring LED chip, so as to electrically connect the LED chips.

According to an embodiment of the present invention, each of the epitaxial layers includes an undoped semiconductor layer, a first conductivity type semiconductor layer, an active layer and a second conductivity type semiconductor layer stacked in sequence on the surface of the insulating substrate, and a conductivity type of the first conductivity type semiconductor layer is different from that of the second conductivity type semiconductor layer.

According to another embodiment of the present invention, before the step of forming the dielectric layer, the method for manufacturing the LED structure further includes forming a plurality of first insulating layers and a plurality of second insulating layers being respectively filled in the first isolation trenches and the second isolation trenches.

According to still another embodiment of the present invention, after the step of forming the first insulating layers and the second insulating layers, the method for manufacturing the LED structure further includes: forming a plurality of current blocking layers respectively located between the epitaxial layers and the second conductivity type contact holes; and forming a plurality of transparent conductive layers respectively located between the dielectric layer and the epitaxial layer. In each of the LED chips, a bottom of the first conductivity type contact hole exposes the first conductivity type semiconductor layer, and a bottom of the second conductivity type contact hole exposes the transparent conductive layer.

According to still another embodiment of the present invention, before the step of forming the interconnection layer, the method for manufacturing the LED structure further includes forming a plurality of insulating liners respectively covering a plurality of sidewalls of the first conductivity type contact holes.

According to still another embodiment of the present invention, the step of forming the first conductivity type contact hole in each of the LED chips includes: removing a part of the second conductivity type semiconductor layer, a part of the active layer and a part of the first conductivity type semiconductor layer, so as to form a groove in the epitaxial layer; filling the dielectric layer in the groove; and removing a part of the dielectric layer, so as to form the first conductivity type contact hole to expose a part of a bottom of the groove, where the dielectric layer covers a sidewall of the groove.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1 is a partial sectional view of a conventional series connected LED structure;

FIG. 2 is a top view of an LED structure according to an embodiment of the present invention;

FIG. 3A is a sectional view of the LED structure taken along Line AA′ of FIG. 2;

FIG. 3B is a sectional view of an LED structure according to another embodiment of the present invention;

FIG. 4 is a sectional view of the LED structure taken along Line BB′ of FIG. 2;

FIG. 5A to FIG. 5J are sectional views illustrating processes of an LED structure according to an embodiment of the present invention; and

FIG. 6A to FIG. 6D are sectional views illustrating processes of an LED structure according to another embodiment of the present invention.

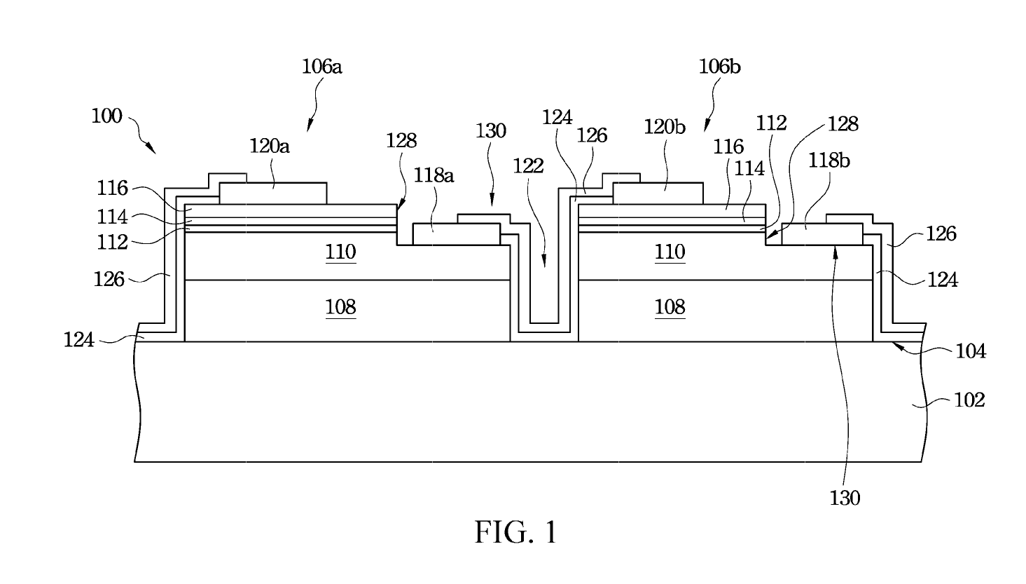

### DETAILED DESCRIPTION OF THE INVENTION

The present invention is more particularly described in the following examples that are intended as illustrative only since numerous modifications and variations therein will be apparent to those skilled in the art. Various embodiments of the invention are now described in detail. Referring to the drawings, like numbers indicate like components throughout the views. As used in the description herein and throughout the claims that follow, the meaning of “a”, “an”, and “the” includes plural reference unless the context clearly dictates otherwise. Also, as used in the description herein and throughout the claims that follow, the meaning of “in” includes “in” and “on” unless the context clearly dictates otherwise. Moreover, titles or subtitles may be used in the specification for the convenience of a reader, which shall have no influence on the scope of the present invention.

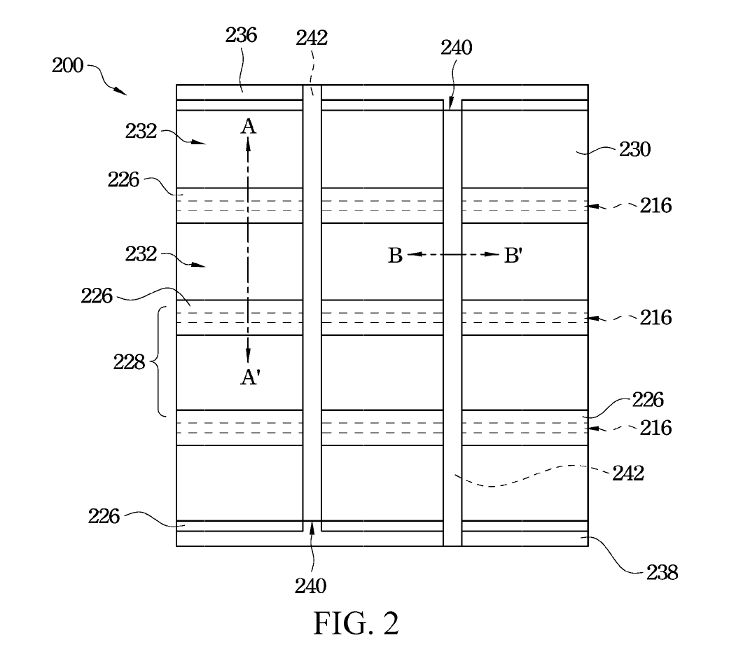

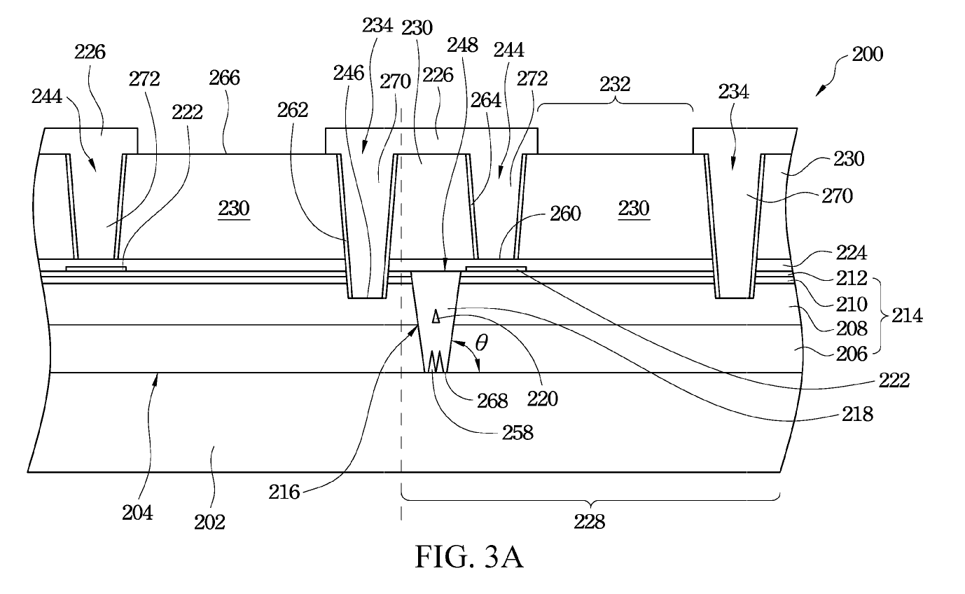

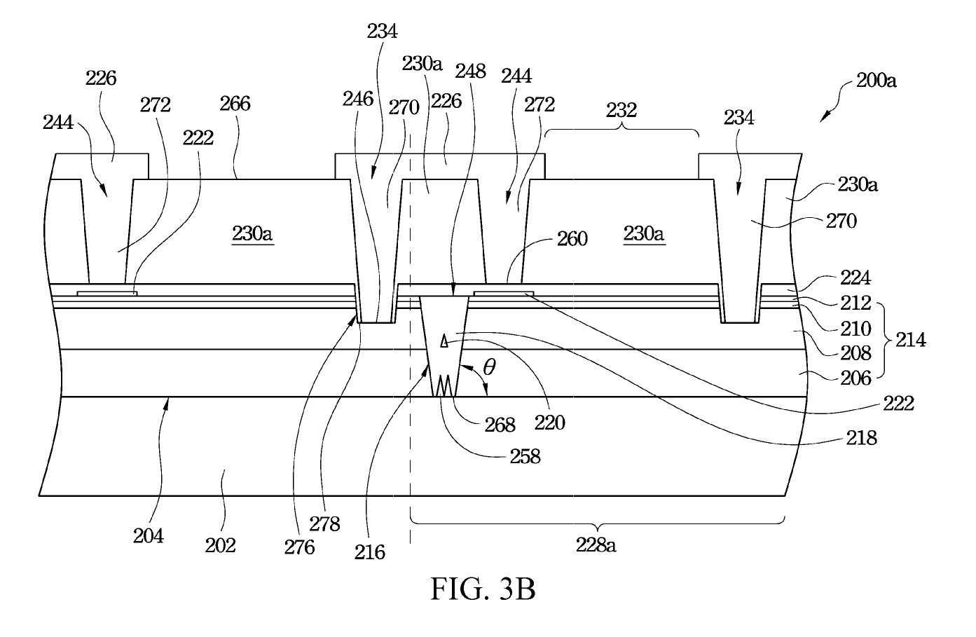

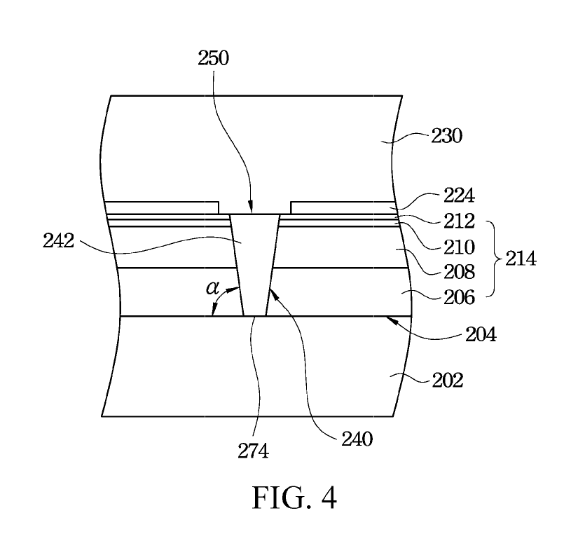

Referring to FIG. 2, FIG. 3A and FIG. 4, where FIG. 2 is a top view of an LED structure according to an embodiment of the present invention, FIG. 3A is a sectional view of an LED structure taken along Line AA′ of FIG. 2, and FIG. 4 is a sectional view of an LED structure taken along Line BB′ of FIG. 2. In this embodiment, the LED structure 200 may be a high voltage LED (HV LED).

The LED structure 200 is formed by connecting a plurality of LED chips 228 in series. In the embodiment shown in FIG. 2, the LED structure 200 is formed by connecting in series 12 LED chips 228 that are arranged in an array manner. Each of the LED chips 228 is provided with isolation trenches 216 and 240 at the periphery thereof, so as to electrically isolate the LED chips 228. Moreover, two neighboring LED chips 228 are electrically connected by a conductive interconnection layer 226, so as to connect all LED chips 228 in series.

In an embodiment, referring to FIG. 2 and FIG. 3A together, the LED structure 200 mainly includes an insulating substrate 202, a plurality of LED chips 228, and a plurality of interconnection layers 226. The material of the insulating substrate 202 may be, for example, sapphire. In some examples, the insulating substrate 202 may be a pattern sapphire substrate (PSS). A plurality of pattern structures 258 are formed on a surface 204 of the insulating substrate 202. By disposing the pattern structures 258, the light extraction efficiency of the LED chips 228 may be improved.

The LED chips 228 are disposed on the surface 204 of the insulating substrate 202. Each of the LED chips 228 includes an epitaxial layer 214 and a dielectric layer 230. In each of the LED chips 228, the epitaxial layer 214 is disposed on the surface 204 of the insulating substrate 202, and the dielectric layer 230 is stacked on the epitaxial layer 214. In this embodiment, the epitaxial layer 214 includes an undoped semiconductor layer 206, a first conductivity type semiconductor layer 208, an active layer 210 and a second conductivity type semiconductor layer 212 that are grown and stacked in sequence on the surface 204 of the insulating substrate 202. In the present invention, the first conductivity type and the second conductivity type are different conductivity types. For example, one of the first conductivity type and the second conductivity type is n type, and the other is p type. In another embodiment, the epitaxial layer 214 may also not include the undoped semiconductor layer 206.

The active layer 210 may be, for example, a multiple quantum well (MQW) structure formed by multiple sets of alternately stacked quantum well layers and barrier layers. In an example, materials of the undoped semiconductor layer 206, the first conductivity type semiconductor layer 208, the active layer 210 and the second conductivity type semiconductor layer 212 may be, for example, GaN-series materials. The dielectric layer 230 may also be referred to as an interlayer dielectric (ILD) layer. The material of the dielectric layer 230 may be an insulating material, such as silicon dioxide (SiO₂) and silicon nitride (SiNₓ).

Each of the LED chips 228 may further selectively include a transparent conductive layer 224. The material of the transparent conductive layer 224 may be, for example, indium tin oxide (ITO). The transparent conductive layer 224 may cover the epitaxial layer 214. By disposing the transparent conductive layer 224, current input to the LED chip 228 may be spread over effectively, thereby avoiding the current crowding effect.

Each of the LED chips 228 has a first conductivity type contact hole 234 and a second conductivity type contact hole 244. The first conductivity type contact hole 234 and the second conductivity type contact hole 244 both penetrate the dielectric layer 230. The first conductivity type contact hole 234 extends from an upper surface 266 of the dielectric layer 230 to the first conductivity type semiconductor layer 208 of the epitaxial layer 214. That is to say, a bottom 246 of the first conductivity type contact hole 234 exposes a part of the first conductivity type semiconductor layer 208.

In another aspect, in the embodiment that the LED chip 228 does not have a transparent conductive layer, the second conductivity type contact hole 244 extends from the upper surface 266 of the dielectric layer 230 to the second conductivity type semiconductor layer 212 of the epitaxial layer 214. That is to say, a bottom 260 of the second conductivity type contact hole 244 exposes a part of the second conductivity type semiconductor layer 212. In the embodiment that the LED chip 228 has the transparent conductive layer 224, as shown in FIG. 3A, the second conductivity type contact hole 244 extends from the upper surface 266 of the dielectric layer 230 only to the transparent conductive layer 224. That is to say, the bottom 260 of the second conductivity type contact hole 244 exposes a part of the transparent conductive layer 224.

Referring to FIG. 3A again, in each of the LED chips 228, the isolation trench 216 is disposed in the epitaxial layer 214, and located between the second conductivity type contact hole 244 of the LED chip 228 and the first conductivity type contact hole 234 of a neighboring LED chip 228. In an embodiment, the isolation trench 216 extends from the second conductivity type semiconductor layer 212 of the epitaxial layer 214 towards the undoped semiconductor layer 206. Therefore, a bottom 268 of the isolation trench 216 is located in the undoped semiconductor layer 206. In the embodiment shown in FIG. 3A, the bottom 268 of the isolation trench 216 may also directly extend to the surface 204 of the insulating substrate 202, so as to expose the surface 204 of the insulating substrate 202. In the embodiment that the epitaxial layer 214 does not include the undoped semiconductor layer 206, the isolation trench 216 extends from the second conductivity type semiconductor layer 212 towards the surface 204 of the insulating substrate 202. Therefore, at this time, the bottom 268 of the isolation trench 216 exposes a part of the surface 204 of the insulating substrate 202. As shown in FIG. 3A, the isolation trench 216 exposes the pattern structures 258 on the surface 204 of the insulating substrate 202.

In some embodiments, each of the LED chips 228 may further include an insulating layer 218. The insulating layer 218 is filled in the isolation trench 216, covers the pattern structures 258 of the insulating substrate 202, and preferably closes an opening 248 of the isolation trench 216. The insulating layer 218 may fill up the isolation trench 216. However, in an embodiment, as shown in FIG. 3A, the insulating layer 218 may not fill up the isolation trench 216, and pores 220 are formed in the isolation trench 216.

In an embodiment, as shown in FIG. 3A, the isolation trench 216 has an inverted trapezoidal shaped section view, so as to facilitate the deposition of the insulating layer 218 into the isolation trench 216. In an example, an angle θ between the isolation trench 216 and the surface 204 of the insulating substrate 202 may be, for example, 30° to 90°. However, in another embodiment, the isolation trench 216 may have a rectangular shaped section view. In addition, the material of the insulating layer 218 may be, for example, SiO₂ or SiN_{X}.

In the embodiment shown in FIG. 3A, to enable the LED chips 228 to operate normally, each of the LED chips 228 further include an insulating liner 262. The insulating liner 262 covers a sidewall of the first conductivity type contact hole 234, so as to electrically isolate the interconnection layer 226 subsequently filled in the first conductivity type contact hole 234 from the transparent conductive layer 224, the second conductivity type semiconductor layer 212, the active layer 210 and the first conductivity type semiconductor layer 208 that are exposed by the sidewall of the first conductivity type contact hole 234. Thereby, it is avoided that the current in the first conductivity type contact hole 234 flows through the transparent conductive layer 224 having smaller resistance to reach the second conductivity type contact hole 244, causing short circuit and being incapable of emitting light. That is to say, by disposing the insulating liner 262, it can be avoided that the first conductivity type semiconductor layer 208 and the second conductivity type semiconductor layer 212 of the same LED chip 228 or neighboring LED chips 228 are directly conducted through the transparent conductive layer 224.

Each of the LED chips 228 may further include an insulating liner 264. The insulating liner 264 covers a sidewall of the second conductivity type contact hole 244, so as to increase the electrical reliability of the LED chip 228. However, in an embodiment, the LED chip 228 may only include the insulating liner 262, and the insulating liner 264 is not required to be disposed. The material of the insulating liners 262 and 264 may be, for example, SiO₂ or SiN_{X}.

In another embodiment, the LED structure may also not include the insulating liner. Referring to FIG. 3B first, a sectional view of an LED structure according to another embodiment of the present invention is shown. In this embodiment, architecture of an LED structure 200a is approximately the same as that of the LED structure 200 in the above embodiment, and the difference between the two lies in that no insulating liner is disposed in the first conductivity type contact hole 234 and the second conductivity type contact hole 244 of an LED chip 228a of the LED structure 200a.

In the LED structure 200a, the epitaxial layer 214 of each of the LED chips 228a is provided with a groove 276. The groove 276 extends from the second conductivity type semiconductor layer 212 of the epitaxial layer 214 towards the first conductivity type semiconductor layer 208. A bottom 278 of the groove 276 is located in the first conductivity type semiconductor layer 208, that is, the bottom 278 of the groove 276 exposes the first conductivity type semiconductor layer 208. The first conductivity type contact hole 234 is connected to the groove 276. Moreover, as shown in FIG. 3B, a part of a dielectric layer 230a covers a sidewall of the groove 276, and the bottom 246 of the first conductivity type contact hole 234 exposes a part of the bottom 278 of the groove 276.

By designing that the dielectric layer 230a extends to cover the sidewall of the groove 276 of the epitaxial layer 214, the LED structure 200a may achieve the effect of electrically insulating the interconnection layer 226 with the epitaxial layer 214 and the transparent conductive layer 224 that are exposed by the sidewall of the groove 276, without the need of additionally disposing an insulating liner on the sidewall of the first conductivity type contact hole 234.

Referring to FIG. 3A again, in the LED structure 200, the interconnection layers 226 respectively connect neighboring LED chips 228, so as to electrically connect the LED chips 228 in series. The interconnection layer 226 is respectively filled in the second conductivity type contact hole 244 of a corresponding LED chip 228, extends from the upper surface 266 of the dielectric layer 230 above the isolation trench 216 to the first conductivity type contact hole 234 of a neighboring LED chip 228, and is filled in the first conductivity type contact hole 234. The parts of the interconnection layer 226 filled in the first conductivity type contact hole 234 and the second conductivity type contact hole 244 may be respectively referred to as contact plugs 270 and 272. The interconnection layer 226 may electrically connect two neighboring LED chips 228 by jointing the transparent conductive layer 224 or second conductivity type semiconductor layer 212 exposed by the second conductivity type contact hole 244 of one LED chip 228, and the first conductivity type semiconductor layer 208 exposed by the first conductivity type contact hole 234 of the neighboring LED chip 228.

In each of the interconnection layers 226, the part located above the two contact plugs 270 and 272 and above the upper surface 266 of the dielectric layer 230 is equivalent to a second conductivity type electrode of one LED chip 228 and a first conductivity type electrode of a neighboring LED chip 228. The material of the interconnection layer 226 is conductive material, for example, metal. In an embodiment, the interconnection layer 226 may be a chromium/platinum/gold (Cr/Pt/Au) stack structure formed by stacking a chromium layer, a platinum layer and a gold layer in sequence.

In an embodiment, each of the LED chips 228 may also selectively include a current blocking layer 222. As shown in FIG. 3A, in each of the LED chips 228, the current blocking layer 222 is disposed on a part of the epitaxial layer 214, and is located below the bottom 260 of the second conductivity type contact hole 244. That is to say, the current blocking layer 222 is located between the bottom 260 of the second conductivity type contact hole 244 and the epitaxial layer 214. Moreover, the transparent conductive layer 224 covers the current blocking layer 222.

By disposing the current blocking layer 222, it can be avoided that a large amount of current directly flow downwards into the LED chip 228 through the contact plug 272 of the interconnection layer 226 to cause current crowding, thereby forcing the current to flow to a light-emitting area 232 through the transparent conductive layer 224. Therefore, the luminous efficiency of the LED chip 228 may be improved greatly. In an embodiment, the current blocking layer 222 is preferably larger than an area of a bottom of the contact plug 272, that is, the current blocking layer 222 preferably covers the whole bottom of the contact plug 272, so as to obtain better current blocking effect.

In another embodiment, the insulating layer 218 may be filled in the isolation trench 216 only to a part of the depth thereof, and it is unnecessary to enable the upper surface of the insulating layer 218 to be aligned with the epitaxial layer 214. In this embodiment, the current blocking layer 222 may extend from the part below the bottom 260 of the second conductivity type contact hole 244 to the opening 248 of the neighboring isolation trench 216, and the current blocking layer 222 covers the opening 248 of the isolation trench 216. By disposing the current blocking layer 222, the insulation effect may be further increased, so as to avoid the transparent conductive layer 224 from covering the epitaxial layer 214 to cause short circuit.

Referring to FIG. 2 and FIG. 4 together, in each of the LED chips 228, another isolation trench 240 is disposed in the epitaxial layer 214 outside the light-emitting area 232, and is adjacent to the isolation trench 216. As shown in FIG. 2, the isolation trench 240 may electrically isolate two neighboring LED chips 228. Therefore, different from the isolation trench 216, no conductive material such as the transparent conductive layer or interconnection layer covers the isolation trench 240, as shown in FIG. 4.

The isolation trench 240 extends from the second conductivity type semiconductor layer 212 of the epitaxial layer 214 to the undoped semiconductor layer 206. In an embodiment, a bottom 274 of the isolation trench 240 may be located in the undoped semiconductor layer 206. In the embodiment shown in FIG. 4, the bottom 274 of the isolation trench 240 directly extends to the surface 204 of the insulating substrate 202, so as to expose a part of the surface 204 of the insulating substrate 202. In the embodiment that the epitaxial layer 214 does not include the undoped semiconductor layer 206, the isolation trench 240 extends from the second conductivity type semiconductor layer 212 towards the surface 204 of the insulating substrate 202, and the bottom 274 of the isolation trench 240 exposes a part of the surface 204 of the insulating substrate 202.

In some embodiments, each of the LED chips 228 may further include another insulating layer 242. The insulating layer 242 is filled in the isolation trench 240, and preferably closes an opening 250 of the isolation trench 240. The insulating layer 242 may fill up the isolation trench 240. However, in another embodiment, the insulating layer 242 may not fill up the isolation trench 240. In an embodiment, as shown in FIG. 4, the isolation trench 240 may have an inverted trapezoidal section, so as to facilitate the deposition of the insulating layer 242 in the isolation trench 240. In an example, an angle α between the isolation trench 240 and the surface 204 of the insulating substrate 202 may be, for example, 30° to 90°. However, in another embodiment, the isolation trench 240 may have a rectangular section. The material of the insulating layer 242 may be, for example, SiO₂ or SiN_{X}. In an embodiment, each of the LED chips 228 may also selectively include a current blocking layer (not shown). The current blocking layer is located above the isolation trench 240, and covers the insulating layer 242 in the isolation trench 240 and the second conductivity type semiconductor layer 212 at the periphery of the opening 250 of the isolation trench 240.

Referring to FIG. 2 again, a front end and a rear end of the LED structure 200 may be respectively provided with a second conductivity type electrode pad 236 and a first conductivity type electrode pad 238. The materials of the first conductivity type electrode pad 238 and the second conductivity type electrode pad 236 may be conductive material, for example, metal. In an embodiment, the first conductivity type electrode pad 238 and the second conductivity type electrode pad 236 may both be a Cr/Pt/Au stack structure formed by stacking a chromium layer, a platinum layer and a gold layer in sequence.

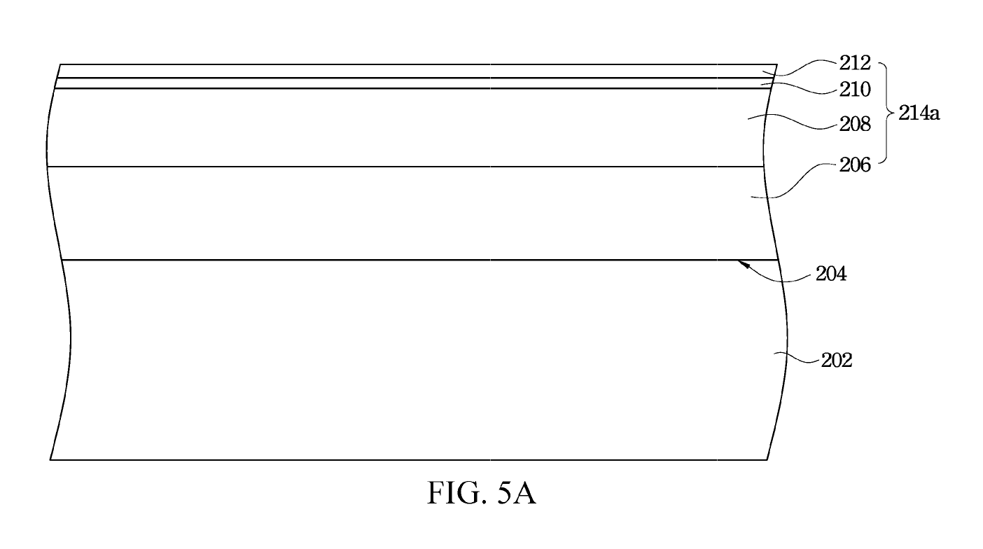

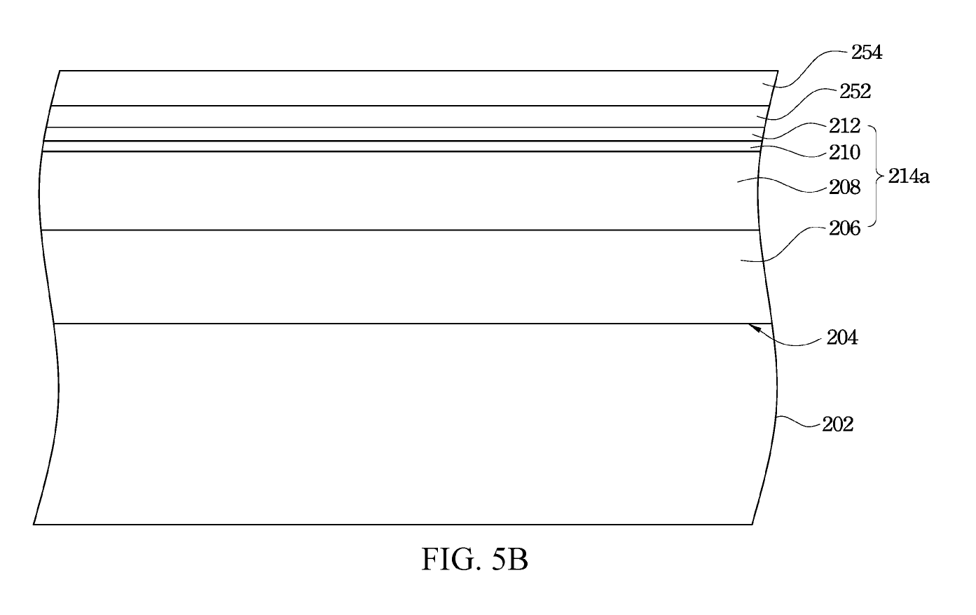

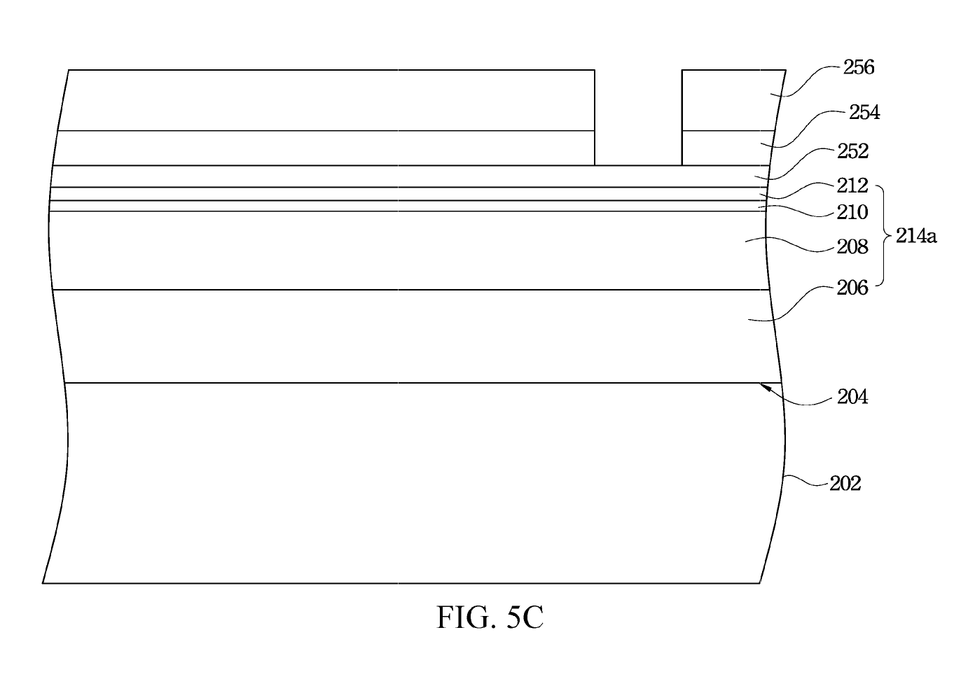

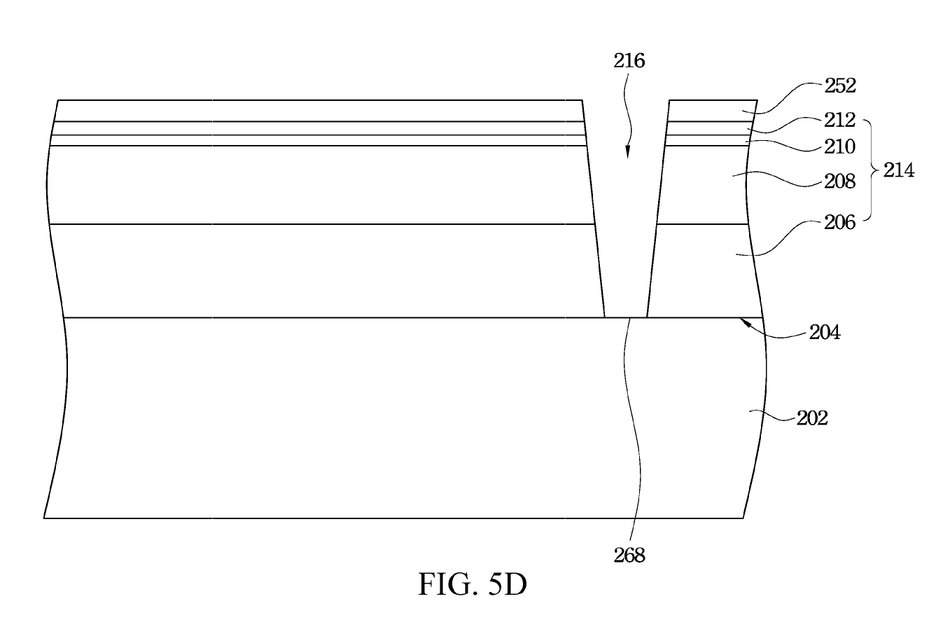

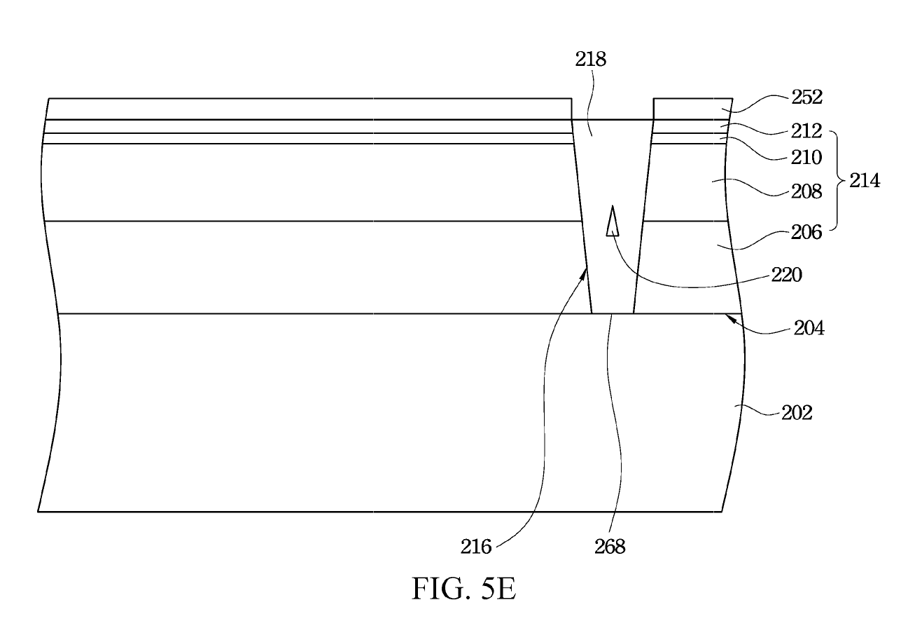

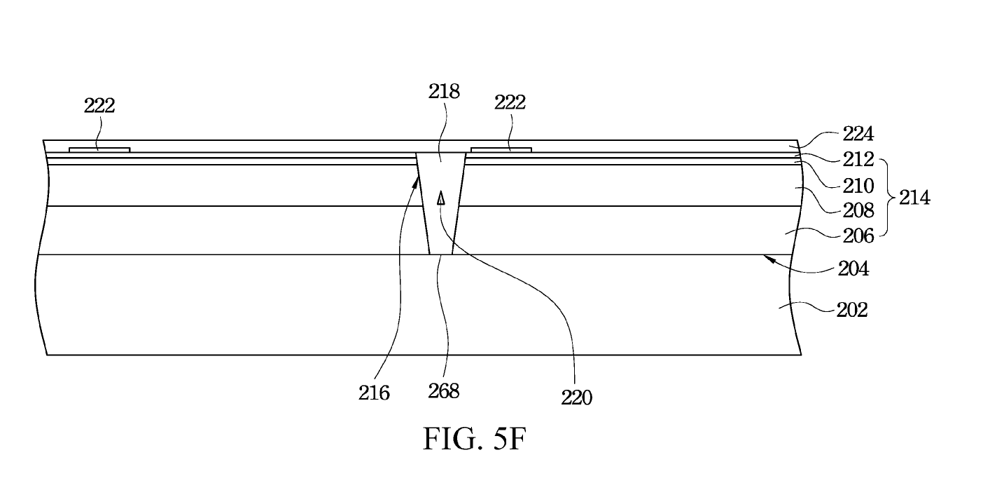

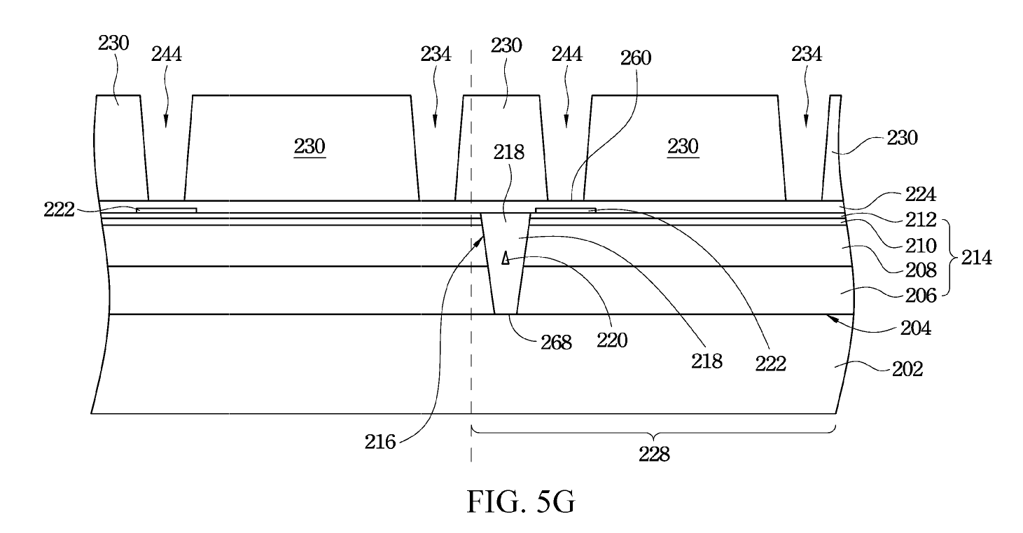

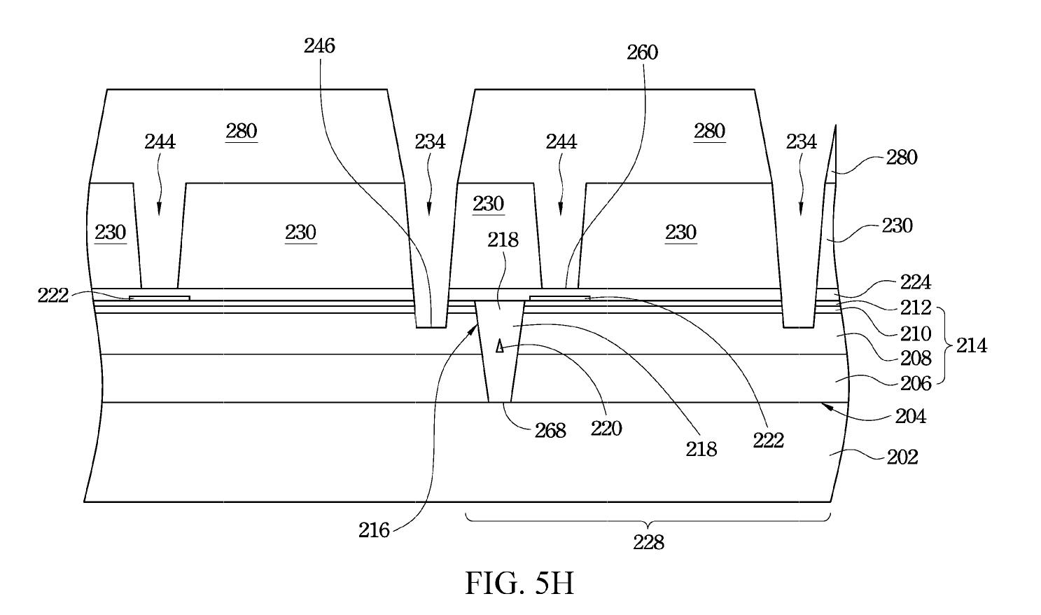

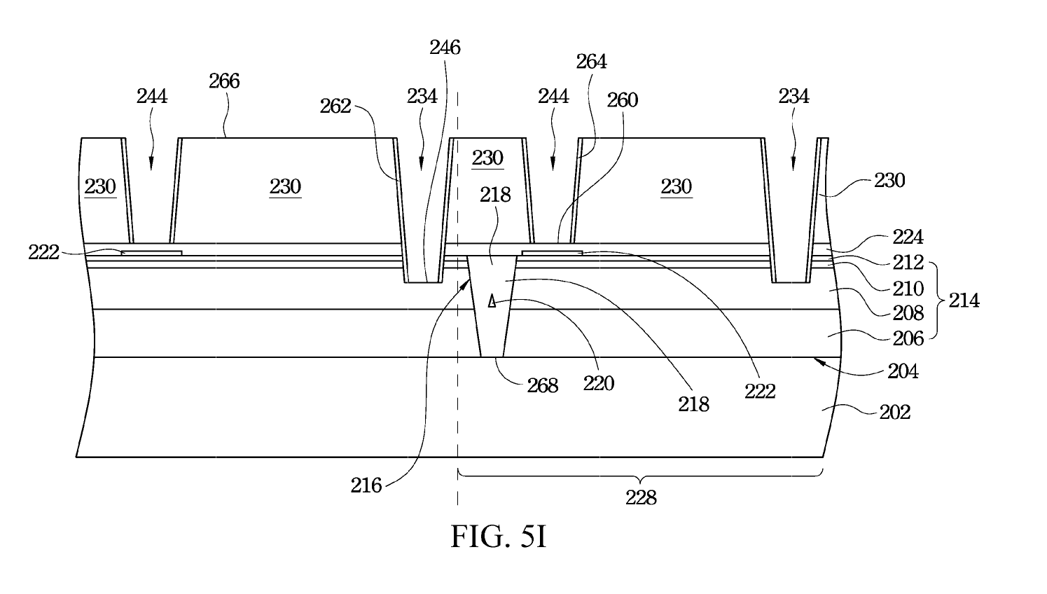

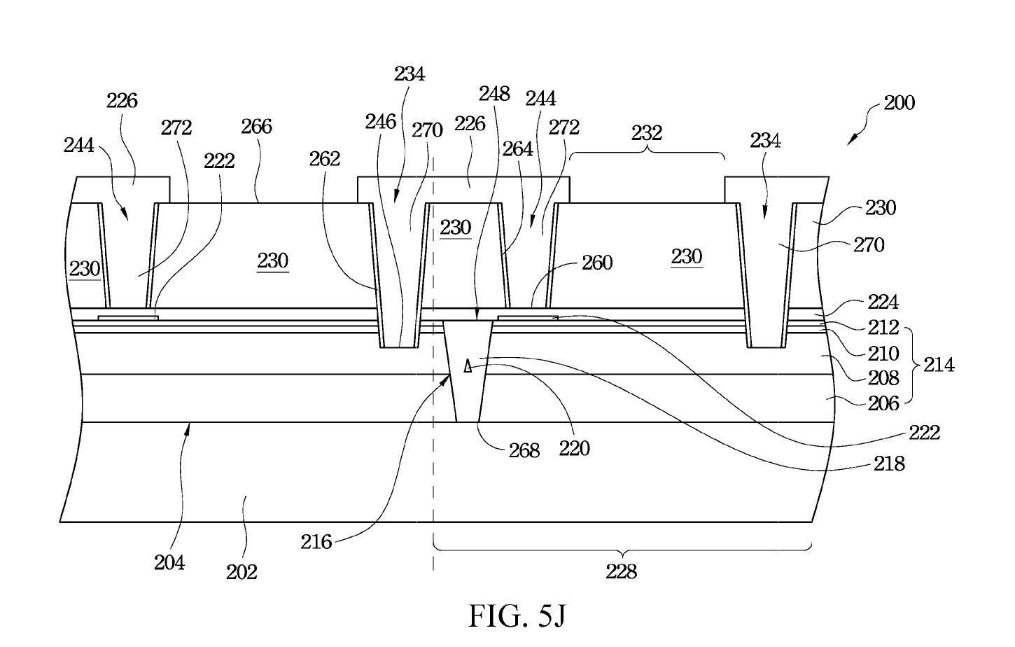

Referring to FIG. 5A-5J, sectional views illustrating processes of an LED structure according to an embodiment of the present invention are shown. In this embodiment, when manufacturing the LED structure 200, an insulating substrate 202, for example, a sapphire substrate, is provided first. In an embodiment, the insulating substrate 202 may be a PSS, and a plurality of pattern structures are disposed on a surface 204 thereof, where the pattern structures may be distributed on the whole surface 204.

Then, an undoped semiconductor layer 206, a first conductivity type semiconductor layer 208, an active layer 210 and a second conductivity type semiconductor layer 212 are formed in sequence on the surface 204 of the insulating substrate 202 by epitaxial growth, for example, Metal Organic Chemical Vapor Deposition (MOCVD). The undoped semiconductor layer 206, the first conductivity type semiconductor layer 208, the active layer 210 and the second conductivity type semiconductor layer 212 are stacked in sequence to form an epitaxial structure 214a. In another embodiment, the epitaxial structure 214a may not include the undoped semiconductor layer 206.

Thereafter, an etching stop layer 252 covering the second conductivity type semiconductor layer 212 is formed by, for example, deposition. The material of the etching stop layer 252 may be, for example, SiN_{X}. As shown in FIG. 5B, a hard mask layer 254 covering the etching stop layer 252 is formed by, for example, deposition. The material of the hard mask layer 254 may be, for example, Ni or SiO₂. The etching stop layer 252 may be used as an etching end when defining a pattern of the hard mask layer 254.

Then, a photoresist layer 256 covering the hard mask layer 254 is formed by, for example, coating. A pattern of the photoresist layer 256 is defined by, for example, a photolithography process. When defining the photoresist layer 256, a part of the photoresist layer 256 is removed to expose a part of the hard mask layer 254, so as to define a predetermined position and shape of the isolation trench 216 in the photoresist layer 256. Thereafter, the exposed part of the hard mask layer 254 is removed by, for example, etching, with the patterned photoresist layer 256 as an etching mask and the etching stop layer 252 as an etching end. Thereby, the pattern in the photoresist layer 256 may be transferred to the hard mask layer 254. Therefore, the predetermined position and shape of the isolation trench 216 previously defined in the photoresist layer 256 may be transferred to the hard mask layer 254, as shown in FIG. 5C.

Then, the epitaxial structure 214a is etched by, for example, inductively coupled plasma (ICP) etching, with the patterned photoresist layer 256 and the hard mask layer 254 as etching masks, so as to remove a part of the second conductivity type semiconductor layer 212, a part of the active layer 210, a part of the first conductivity type semiconductor layer 208 and a part of the undoped semiconductor layer 206. Thereby, as shown in FIG. 4 and FIG. 5C, the pattern in the hard mask layer 254 may be further transferred to the epitaxial structure 214a, so as to form the isolation trenches 216 and 240 in the epitaxial structure 214a. As shown in FIG. 2 and FIG. 5D, the isolation trenches 216 are respectively adjacent to the isolation trenches 240, and the isolation trenches 216 and 240 define the epitaxial structure 214a into the epitaxial layers 214 of a plurality of LED chips 228. Each of the LED chips 228 includes an isolation trench 216, and an isolation trench 240 may be disposed between two neighboring LED chips 228.

In an embodiment, as shown in FIG. 4 and FIG. 5D, the bottom 268 of the isolation trench 216 and the bottom 274 of the isolation trench 240 both expose a part of the surface 204 of the insulating substrate 202. In another embodiment, the bottom 268 of the isolation trench 216 and the bottom 274 of the isolation trench 240 may be located in the undoped semiconductor layer 206. In the embodiment that the epitaxial layer 214 does not include the undoped semiconductor layer 206, the isolation trenches 216 and 240 extend from the second conductivity type semiconductor layer 212 towards the surface 204 of the insulating substrate 202, and the isolation trenches 216 and 240 both expose a part of the surface 204 of the insulating substrate 202.

In an embodiment, after forming the isolation trenches 216 and 240, the residual photoresist layer 256 and hard mask layer 254 may be removed to expose the etching stop layer 252, so as to form the structure shown in FIG. 5D. In another embodiment, the etching stop layer 252 covering the second conductivity type semiconductor layer 212 may be formed after removing the photoresist layer 256 and the hard mask layer 254.

According to product requirements, an insulating material covering the etching stop layer 252 and filled in the isolation trenches 216 and 240 may be selectively formed by, for example, plasma enhanced chemical vapor deposition (PECVD). The insulating material may be, for example, SiO₂ or SiN_{X}. In an embodiment, the insulating material on the etching stop layer 252 may be removed by, for example, etch back, with the etching stop layer 252 as an etching end, so as to respectively fill the insulating layers 218 and 242 into the isolation trenches 216 and 240, as shown in FIG. 5E and FIG. 4. In other embodiments, an excessive part of the insulating material on the etching stop layer 252 may be removed by, for example, chemical mechanical polishing (CMP). At this time, the etching stop layer 252 serves as a polishing end.

The insulating layers 218 and 242 preferably respectively close the opening 248 of the isolation trench 216 and the opening 250 of the isolation trench 240. In an embodiment, the insulating material may fill up the isolation trenches 216 and 240. In another embodiment, as shown in FIG. 5E, the insulating material may also not fill up the isolation trenches 216 and 240, and pores 220 are formed in the isolation trenches 216 and 240.

After the insulating layers 218 and 242 are formed, the etching stop layer 252 may be removed to expose the second conductivity type semiconductor layer 212. In an embodiment, the dielectric layer 230 may be directly formed. However, in another embodiment, a current blocking material covering the second conductivity type semiconductor layer 212 may be selectively formed by, for example, deposition. A part of the current blocking material on the second conductivity type semiconductor layer 212 is removed by, for example, photolithography and etching, so as to from a plurality of current blocking layers 222 on a predetermined area of the second conductivity type semiconductor layer 212, as shown in FIG. 5F. The material of the current blocking layer 222 may be, for example, SiO₂.

As shown in FIG. 5F, in the embodiment where the current blocking layer 222 is disposed, the transparent conductive layer 224 covering the current blocking layer 222, the second conductivity type semiconductor layer 212 and the insulating layer 218 may be further formed by, for example, evaporation or sputtering. The material of the transparent conductive layer 224 may be, for example, ITO.

A dielectric material layer is formed to cover the transparent conductive layer 224. The dielectric material may be an insulating material, such as SiO₂ and SiN_{X}. In an embodiment, the dielectric material layer may be formed by, for example, PECVD, where the thickness of the dielectric material layer may be about 2000 Å to 3000 Å. In another embodiment, the dielectric material layer may be formed by, for example, spin coating, where the thickness of the dielectric material layer may be about 2 μm to 3 μm.

After the dielectric material layer is formed, according to an actual process requirement, the dielectric material layer may be flattened selectively by, for example, CMP, so as to obtain the dielectric material layer having a substantially flat surface. Then, as shown in FIG. 5G, a part of the dielectric material layer is removed by, for example, photolithography and etching such as ICP etching, so as to from a part of a plurality of first conductivity type contact holes 234 and a plurality of second conductivity type contact holes 244, and form a plurality of dielectric layers 230. Each of the LED chips 228 includes a dielectric layer 230, and a part of the first conductivity type contact holes 234 and the second conductivity type contact holes 244 penetrate the dielectric layer 230.

A photoresist layer 280 is formed to cover the dielectric layer 230, and be filled in the first conductivity type contact holes 234 and the second conductivity type contact holes 244. A pattern of the photoresist layer 280 is defined by, for example, a photolithography process. When defining the photoresist layer 280, the photoresist layer 280 in the first conductivity type contact hole 234 is removed, so as to expose the transparent conductive layer 224 in the first conductivity type contact hole 234. Thereafter, the exposed part of the transparent conductive layer 224 and the second conductivity type semiconductor layer 212, the active layer 210 and a part of the first conductivity type semiconductor layer 208 that are located below the transparent conductive layer 224 are removed by, for example, etching, with the patterned photoresist layer 280 as an etching mask, thereby forming the first conductivity type contact holes 234. As shown in FIG. 5H, the isolation trench 216 of each of the LED chips 228 is located between the second conductivity type contact hole 244 thereof and the first conductivity type contact hole 234 of the neighboring LED chip 228.

As shown in FIG. 5H, in each of the LED chips 228, the bottom 246 of the first conductivity type contact hole 234 exposes a part of the first conductivity type semiconductor layer 208, and is located in the first conductivity type semiconductor layer 208. The bottom 260 of the second conductivity type contact hole 244 exposes a part of the transparent conductive layer 224. In addition, the current blocking layer 222 is located between the second conductivity type semiconductor layer 212 of the epitaxial layer 214 and the bottom 260 of the second conductivity type contact hole 244. The transparent conductive layer 224 covers the current blocking layer 222, and is located between the second conductivity type semiconductor layer 212 of the epitaxial layer 214 and the dielectric layer 230. In another embodiment, the LED chip 228 does not have the transparent conductive layer, and the bottom 260 of the second conductivity type contact hole 244 exposes a part of the second conductivity type semiconductor layer 212.

Next, the residual photoresist layer 280 may be removed to expose the dielectric layer 230, the first conductivity type contact hole 234 and the second conductivity type contact hole 244. An insulating material layer covering the dielectric layer 230, the sidewall and the bottom 246 of the first conductivity type contact hole 234, and the sidewall and the bottom 260 of the second conductivity type contact hole 244 is further formed by, for example, PECVD. The material of the insulating material layer may be, for example, SiO₂ or SiN_{X}. Then, the insulating material layer on the upper surface 266 of the dielectric layer 230, on the bottom 246 of the first conductivity type contact hole 234 and on the bottom 260 of the second conductivity type contact hole 244 may be removed by anisotropic etching such as dry etching, so as to respectively form insulating liners 262 and 264 on the sidewall of the first conductivity type contact hole 234 and the sidewall of the second conductivity type contact hole 244, as shown in FIG. 5I.

Then, a conductive layer covering the upper surface 266 of the dielectric layer 230 and filled in the first conductivity type contact hole 234 and the second conductivity type contact hole 244 is formed by, for example, deposition method. A part of the metal layer is removed by, for example, photolithography and etching, so as to form a plurality of interconnection layers 226, a first conductivity type electrode pad 238 and a second conductivity type electrode pad 236, thereby forming the series LED structure 200, as shown in FIG. 5J. The parts of each interconnection layer 226 that are filled in the first conductivity type contact hole 234 and the second conductivity type contact hole 244 may also be respectively referred to as contact plugs 270 and 272. The materials of the interconnection layer 226, the first conductivity type electrode pad 238 and the second conductivity type electrode pad 236 may be, for example, metal. In an embodiment, the interconnection layer 226, the first conductivity type electrode pad 238 and the second conductivity type electrode pad 236 may be a Cr/Pt/Au stack structure formed by stacking a chromium layer, a platinum layer and a gold layer in sequence.

Referring to FIG. 2 again, the first conductivity type electrode pad 238 and the second conductivity type electrode pad 236 are respectively disposed on the front end and the rear end of the LED structure 200. Moreover, the interconnection layers 226 respectively connect neighboring LED chips 228, so as to electrically connect the LED chips 228 in series. As shown in FIG. 5J, the interconnection layer 226 extends from the exposed part of the first conductivity type semiconductor layer 208 in the first conductivity type contact hole 234 of one of the two neighboring LED chips 228, through the upper surface 266 of the dielectric layer 230 above the isolation trench 216 of a neighboring LED chip 228, onto and filled in the second conductivity type contact hole 244 of the neighboring LED chip 228, so as to be in contact with the exposed part of the transparent conductive layer 224 of the neighboring LED chip 228. Therefore, the interconnection layer 226 may electrically connect the two neighboring LED chips 228.

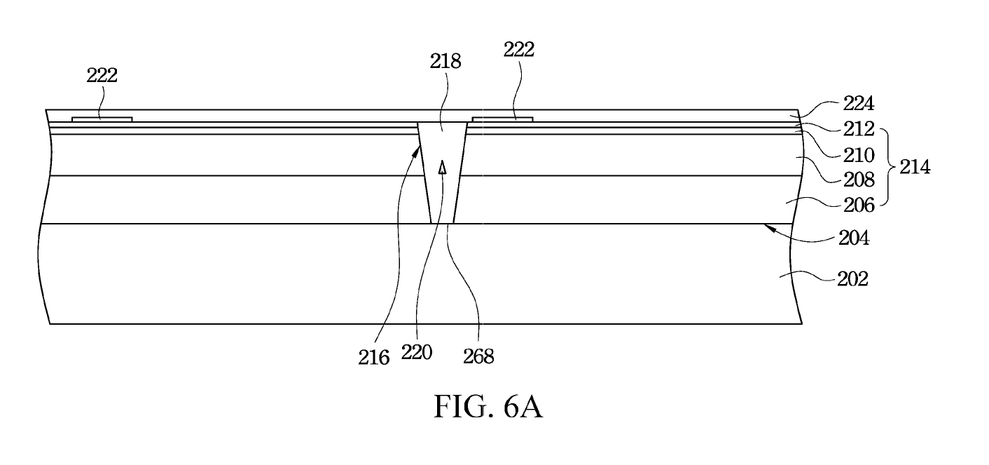

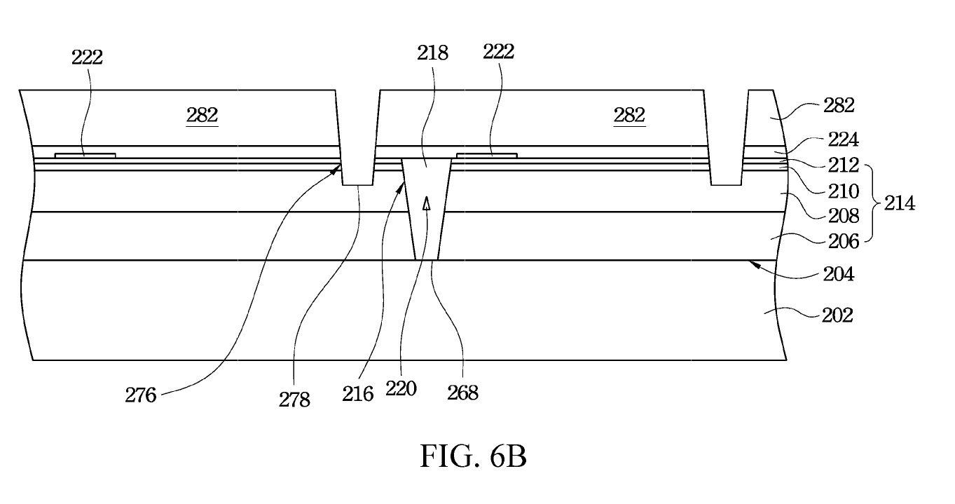

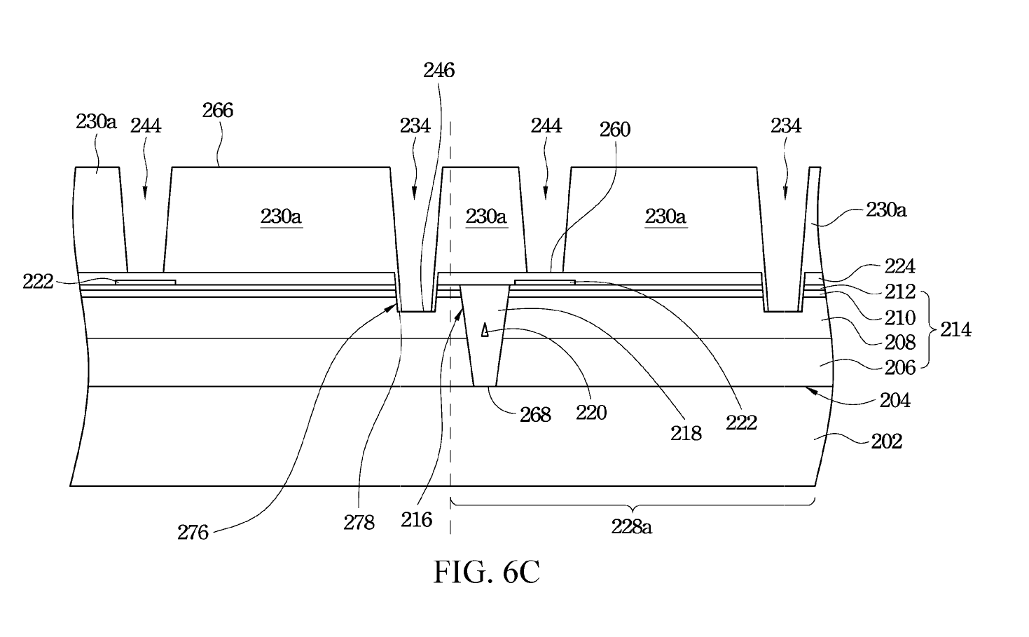

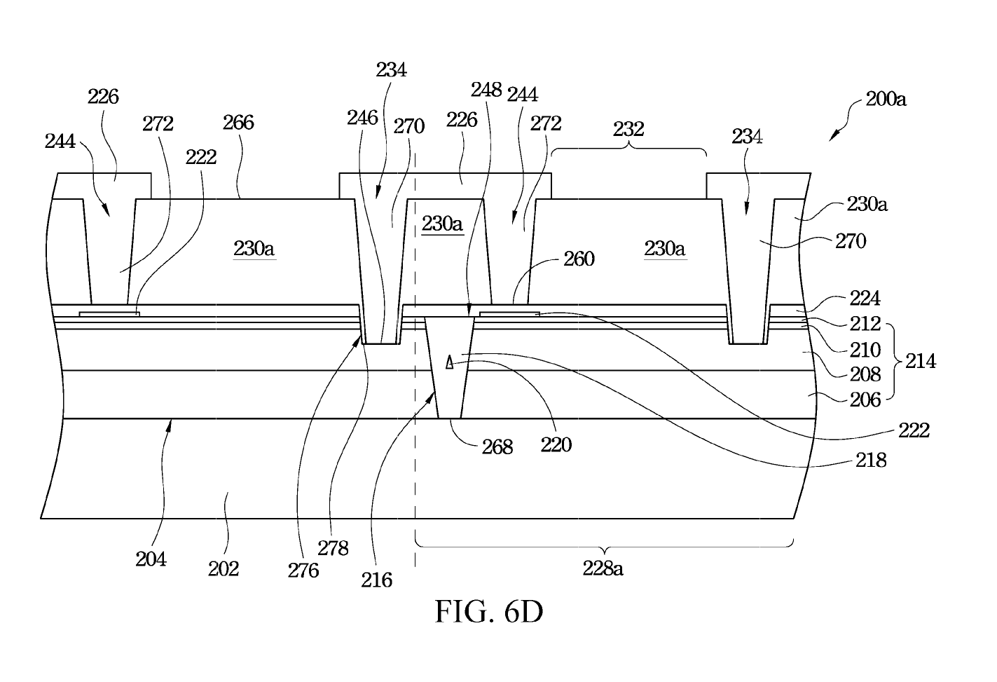

Referring to FIG. 6A-6D, sectional views illustrating processes of an LED structure according to another embodiment of the present invention are shown. In this embodiment, the structure shown in FIG. 6A may be formed according to the process steps in the above embodiment. The structure shown in FIG. 6A is the same as the structure shown in FIG. 5F.

Then, a photoresist layer 282 covering the transparent conductive layer 224 is formed by, for example, coating. A pattern of the photoresist layer 282 is defined by, for example, photolithography process. When defining the photoresist layer 282, a part of the photoresist layer 282 is removed to expose a part of the transparent conductive layer 244, so as to define a predetermined position and shape of the groove 276 in the photoresist layer 282. Thereafter, as shown in FIG. 6B, the exposed part of the transparent conductive layer 224, and a part of the second conductivity type semiconductor layer 212, a part of the active layer 210 and a part of the first conductivity type semiconductor layer 208 that are located below the transparent conductive layer 224 are removed by, for example, etching, with the patterned photoresist layer 282 as an etching mask, so as to form the groove 276 in the epitaxial layer 214. The bottom 278 of the groove 276 exposes a part of the first conductivity type semiconductor layer 208.

The residual photoresist layer 282 is removed to expose the transparent conductive layer 224 and the groove 276. A dielectric material layer covering the transparent conductive layer 224 and filled in the groove 276 is formed by, for example, PECVD or spin coating. The dielectric material is an insulating material, such as SiO₂ and SiN_{X}. After the dielectric material layer is formed, the dielectric material layer may be flattened selectively by, for example, CMP, according to an actual processing requirement, so as to obtain the dielectric material layer having a substantially flat surface.

As shown in FIG. 6C, a part of the dielectric material layer is removed by, for example, photolithography and etching such as ICP etching, so as to form a plurality of first conductivity type contact holes 234 and a plurality of second conductivity type contact holes 244, and form a plurality of dielectric layers 230a. Each of the LED chips 228a includes a dielectric layer 230a, and the first conductivity type contact holes 234 and second conductivity type contact holes 244 penetrate the dielectric layer 230a. As shown in FIG. 6C, the isolation trench 216 of each LED chip 228a is located between the second conductivity type contact hole 244 thereof and the first conductivity type contact hole 234 of the neighboring LED chip 228a.

As shown in FIG. 6C, in each of the LED chips 228a, a part of the dielectric layer 230a covers the sidewall of the groove 276, and the bottom 246 of the first conductivity type contact hole 234 exposes a part of the bottom 278 of the groove 276. The bottom 260 of the second conductivity type contact hole 244 exposes a part of the transparent conductive layer 224. In this embodiment, the dielectric layer 230a extends to cover the sidewall of the groove 276, so the LED structure 200a may enable the interconnection layer 226 to be electrically insulated with the epitaxial layer 214 and the transparent conductive layer 224 that are exposed by the sidewall of the and groove 276, without the need of additionally disposing an insulating liner on the sidewall of the first conductivity type contact hole 234.

A conductive layer covering the upper surface 266 of the dielectric layer 230a and filled in the first conductivity type contact hole 234 and the second conductivity type contact hole 244 is formed by, for example, deposition. A part of the metal layer is removed by, for example, photolithography and etching, so as to form a plurality of interconnection layers 226, a first conductivity type electrode pad and a second conductivity type electrode pad (for example, the first conductivity type electrode pad 238 and the second conductivity type electrode pad 236 shown in FIG. 2), thereby forming the series LED structure 200a, as shown in FIG. 6D. The parts of each of the interconnection layers 226 that are filled in the first conductivity type contact hole 234 and the second conductivity type contact hole 244 may also be respectively referred to as contact plugs 270 and 272. The materials of the interconnection layer 226, the first conductivity type electrode pad and the second conductivity type electrode pad may be, for example, metal. In an embodiment, the interconnection layer 226, the first conductivity type electrode pad and the second conductivity type electrode pad may be a Cr/Pt/Au stack structure formed by stacking a chromium layer, a platinum layer and a gold layer in sequence.

As shown in FIG. 6D, the interconnection layer 226 extends from the exposed part of the first conductivity type semiconductor layer 208 in the first conductivity type contact hole 234 of one of two neighboring LED chips 228a, through the upper surface 266 of the dielectric layer 230a above the isolation trench 216 of the neighboring LED chip 228a, onto and is filled in the second conductivity type contact hole 244 of the neighboring LED chip 228a, so as to be in contact with the exposed part of the transparent conductive layer 224 of the neighboring LED chip 228a. Therefore, the interconnection layer 226 may electrically connect the two neighboring LED chips 228a.

It can be seen from the above embodiment that, among other things, one advantage of the present invention lies in that, the interconnection layer of the LED structure directly extends from the contact hole in the dielectric layer above one of the neighboring LED chips, through the above of the dielectric layer, onto the contact hole in the dielectric layer above the other one of the neighboring LED chips. Therefore, the conductive material may not need to be filled in the isolation trench between the two neighboring LED chips, thereby solving the disconnection problem of the interconnection layer.

It can be seen from the above embodiment that, another advantage of the present invention lies in that, the isolation trench between the two neighboring LED chips of the LED structure is only filled with the insulating layer without any conductive material. Therefore, even if the deposition of the insulating layer in the isolation trench is discontinuous, in the condition that no conductive material exists in the isolation trench, no short circuit problem occurs in the light-emitting area.

It can be seen from the above embodiment that, still another advantage of the present invention lies in that, the method for manufacturing the LED structure may effectively solve the short circuit and disconnection problems, so that the production yield of the series LED structure may be improved greatly, thereby reducing the manufacturing cost.

It can be seen from the above embodiment that, yet another advantage of the present invention lies in that, the short circuit and disconnection problems may be effectively solved, so that the reverse leakage current detection means is not required.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light-emitting diode (LED) structure, comprising:
an insulating substrate;
a plurality of LED chips, wherein each of the LED chips comprises an epitaxial layer and a dielectric layer stacked in sequence on a surface of the insulating substrate, and each of the LED chips is provided with:
a first conductivity type contact hole and a second conductivity type contact hole that penetrate the dielectric layer; and
a first isolation trench, located in the epitaxial layer, and between the second conductivity type contact hole of the LED chip and the first conductivity type contact hole of the neighboring LED chip; and
a plurality of interconnection layers, wherein each of the interconnection layers extends from the second conductivity type contact hole of each of the LED chip, through the above of the first isolation trench, onto the first conductivity type contact hole of the neighboring LED chip, so as to electrically connect the LED chips.

2. The LED structure according to claim 1, wherein in each of the LED chips, a bottom of the first isolation trench exposes the surface of the insulating substrate.

3. The LED structure according to claim 1, wherein each of the epitaxial layers comprises an undoped semiconductor layer, a first conductivity type semiconductor layer, an active layer and a second conductivity type semiconductor layer stacked in sequence on the surface of the insulating substrate, and a conductivity type of the first conductivity type semiconductor layer is different from that of the second conductivity type semiconductor layer.

4. The LED structure according to claim 3, wherein in each of the LED chips, a bottom of the first isolation trench exposes the undoped semiconductor layer.

5. The LED structure according to claim 3, wherein in each of the LED chips, a bottom of the first conductivity type contact hole exposes the first conductivity type semiconductor layer, and a bottom of the second conductivity type contact hole exposes the second conductivity type semiconductor layer.

6. The LED structure according to claim 3, wherein
each of the LED chips further comprises a transparent conductive layer located between the dielectric layer and the epitaxial layer;
a bottom of the first conductivity type contact hole exposes the first conductivity type semiconductor layer; and
a bottom of the second conductivity type contact hole exposes the transparent conductive layer.

7. The LED structure according to claim 6, wherein each of the LED chips further comprises at least one current blocking layer located between the bottom of the second conductivity type contact hole and the epitaxial layer.

8. The LED structure according to claim 3, wherein in each of the LED chips, the epitaxial layer has a groove, the first conductivity type contact hole exposes a part of a bottom of the groove, and the dielectric layer covers a sidewall of the groove.

9. The LED structure according to claim 1, wherein each of the LED chips further comprises an insulating layer, and the insulating layer is filled in the first isolation trench, so as to close an opening of the first isolation trench.

10. The LED structure according to claim 1, wherein each of the LED chips further comprises at least one insulating liner covering a sidewall of the first conductivity type contact hole.

11. The LED structure according to claim 1, wherein the insulating substrate is a pattern sapphire substrate (PSS).

12. A method for manufacturing a light-emitting diode (LED) structure, comprising:
providing an insulating substrate;
forming an epitaxial structure on a surface of the insulating substrate;
forming a plurality of first isolation trenches and a plurality of second isolation trenches in the epitaxial structure, so as to define a plurality of epitaxial layers of a plurality of LED chips, wherein the first isolation trenches are respectively adjacent to the second isolation trenches;
forming a plurality of dielectric layers respectively covering the epitaxial layers;
forming, in each of the LED chips, a first conductivity type contact hole and a second conductivity type contact hole that penetrate the dielectric layer, wherein the first isolation trench in each of the LED chips is located between the second conductivity type contact hole of the LED chip and the first conductivity type contact hole of the neighboring LED chip; and
forming a plurality of interconnection layers, wherein each of the interconnection layers extends from the second conductivity type contact hole of each of the LED chips, through the above of the first isolation trench, onto the first conductivity type contact hole of the neighboring LED chip, so as to electrically connect the LED chips.

13. The method for manufacturing an LED structure according to claim 12, wherein each of the epitaxial layers comprises an undoped semiconductor layer, a first conductivity type semiconductor layer, an active layer and a second conductivity type semiconductor layer stacked in sequence on the surface of the insulating substrate, and a conductivity type of the first conductivity type semiconductor layer is different from that of the second conductivity type semiconductor layer.

14. The method for manufacturing an LED structure according to claim 13, before the step of forming the dielectric layers, further comprising forming a plurality of first insulating layers and a plurality of second insulating layers being respectively filled in the first isolation trenches and the second isolation trenches.

15. The method for manufacturing an LED structure according to claim 14, wherein the step of forming the first insulating layers and the second insulating layers further comprises:
forming an insulating material coving the epitaxial structure and filled in the first isolation trenches and the second isolation trenches; and
performing an etch back step to remove a part of the insulating material.

16. The method for manufacturing an LED structure according to claim 15, after the step of forming the first insulating layers and the second insulating layers, further comprising:
forming a plurality of current blocking layers respectively located between the epitaxial layers and the second conductivity type contact holes; and
forming a plurality of transparent conductive layers respectively located between the dielectric layer and the epitaxial layer.

17. The method for manufacturing an LED structure according to claim 16, wherein in each of the LED chips, a bottom of the first conductivity type contact hole exposes the first conductivity type semiconductor layer, and a bottom of the second conductivity type contact hole exposes the transparent conductive layer.

18. The method for manufacturing an LED structure according to claim 13, wherein in each of the LED chips, a bottom of the first conductivity type contact hole exposes the first conductivity type semiconductor layer, and a bottom of the second conductivity type contact hole exposes the second conductivity type semiconductor layer.

19. The method for manufacturing an LED structure according to claim 13, before the step of forming the interconnection layers, further comprising forming a plurality of insulating liners respectively covering a plurality of sidewalls of the first conductivity type contact holes.

20. The method for manufacturing an LED structure according to claim 13, wherein the step of forming the first conductivity type contact hole in each of the LED chips comprises:
removing a part of the second conductivity type semiconductor layer, a part of the active layer and a part of the first conductivity type semiconductor layer, so as to form a groove in the epitaxial layer;
filling the dielectric layer in the groove; and
removing a part of the dielectric layer, so as to form the first conductivity type contact hole to expose a part of a bottom of the groove, wherein the dielectric layer covers a sidewall of the groove.
